(19) United States
(12) Patent Application Publication
(10) Pub. No.: US 2012/0193728 A1
(43) Pub. Date: Aug. 2, 2012

(54) SEMICONDUCTOR DEVICE AND MANUFACTURING METHOD THEREFOR

(75) Inventor: Takeo MATSUKI, Kanagawa (JP)

(73) Assignee: RENESAS ELECTRONICS CORPORATION, Kanagawa (JP)

(21) Appl. No.: 13/343,735

(22) Filed: Jan. 5, 2012

(30) Foreign Application Priority Data
Jan. 27, 2011 (JP) 2011-015381

(51) Int. Cl. H01L 29/772; H01L 21/28

(52) U.S. Cl. 257/411; 438/591; 257/E29.242; 257/E21.19

(57) ABSTRACT

A semiconductor device includes a semiconductor substrate, a first gate insulating film, a silicon-containing second gate insulating film, and a first gate electrode. The first gate insulating film is formed on the semiconductor substrate and made of a material having a dielectric constant higher than a dielectric constant of silicon oxide or silicon oxynitride. The silicon-containing second gate insulating film is formed on the first gate insulating film. The first gate electrode is formed on the silicon-containing second gate insulating film and includes a metal nitride layer. The first gate insulating film, the silicon-containing second gate insulating film and the metal nitride layer form part of the pMOSFET.

### CROSS-REFERENCE TO RELATED APPLICATIONS

The disclosure of Japanese patent Application No. 2011-15381 filed on Jan. 27, 2011 including the specification drawings and abstract is incorporated herein by reference in its entirety.

### BACKGROUND

The present invention relates to a semiconductor device having a high dielectric constant gate insulating film and a gate electrode made of metal nitride, and a semiconductor manufacturing method.

As a related art having an object of reducing the gate leak current and enhancing the current driving capacity of the Metal-Oxide Semiconductor Field-Effect transistor (MOSFET), there is a technique of forming a gate insulating film by using an insulating material (high-k material) having a dielectric constant higher than that of SiO₂ or SiON and forming a gate electrode by using a metal or a metal nitride film (for example, Patent Document 1). When a metal nitride film is used to form a gate electrode, there was a problem that when impurities introduced into source/drain regions are electrically activated by a high temperature thermal treatment, an apparent work function of the gate electrode varies. As a solution to that problem, it is reported that the apparent work function can be controlled by changing the thickness of metal nitride (Non-Patent Document 1). According to Non-Patent Document 1, the apparent work function becomes larger by increasing the thickness of TiN. That is, as the thickness of TiN increases, a threshold voltage Vt of the nMOSFET increases and a threshold voltage Vt of the pMOSFET drops. To enhance the current driving capacity, drop of the threshold voltage Vt is desirable.

As a technology to control the threshold voltage Vt in metal/high-k stack layers to a low level, a technique of incorporating La rare-earth such as Y and AI into an Hf oxide film or an Hf silicate film is reported. It is known that La rare earth (Non-Patent Document 3) Y shifts flat band voltage Vfb in a negative direction, and Al shifts the flat band voltage Vfb in a positive direction. To increase the ON-current, the former is advantageous for the nMOSFET, and the latter for the pMOSFET (Non-Patent Documents, 3, 4 and 5). In order to incorporate the above-mentioned materials into each of the nMOSFET and the pMOSFET of a CMOSFET while reducing the number of manufacturing steps, a method of incorporating both of the elements into one of gate insulating films has been proposed (Non-Patent Document 6). Non-Patent Document 6 discloses a method of controlling nitrogen distribution in a gate insulating film by capturing nitrogen into a thin SiN layer which is inserted into an HfON gate insulating film during the formation thereof. Further, Non-Patent Document 6 describes the Si layer insertion improves a variation life time of the threshold voltage, a so-called Negative Bias Temperature Instability (NBTI), which results from a long-time ON operation in the pMOSFET. It is said that the improvement owes to effects of the Si layer insertion which reduces the interface state existing at an interface between the gate insulating film and Si substrate.

### PATENT DOCUMENT 1

Japanese Patent Laid-open Publication No. 2010-161308

### Non-Patent Document 1

“Improved FET characteristics by laminate design optimization of metal gates—Guidelines for optimizing metal gate stack structure “, M. Kadoshima, et al., 2008 Symposium on VLSI Technology Digest of Technical Papers, pp. 48-49.

### Non-Patent Document 2

“DETRIMENTAL IMPACT OF TECHNOLOGICAL PROCESSES ON BTI RELIABILITY OF ADVANCED HIGH-K/METAL GATE STACKS”, X. Garros, et al., Proceedings of 47th Annual International Reliability Physics, pp. 362-366.

### Non-Patent Document 3

“Novel Process To Pattern Selectively Dual Dielectric Capping Layers Using Soft-Mask Only”, T. Schram, et al., 2008 Symposium on VLSI Technology Digest of Technical Papers, pp. 44-45.

### Non-Patent Document 4

“Systematic Study of Vth Controllability Using ALD-Y2O3, La2O3, and MgO2 Layers with HfSiON/Metal Gate First n-MOSFETs for hp 32 nm Bulk Devices” S. Kamiyama, et al., 2008 International Electron Device Meeting Digest of technical papers, pp. 41-44.

### Non-Patent Document 5

“The Impact of Stacked Cap Layers on Effective Work Function With HfSiON and SiON Gate Dielectrics” Hag-Ju Cho, et al., IEEE ELECTRON DEVICE LETTERS, VOL. 29, NO. 7, JULY 2008, pp. 743-745.

### Non-Patent Document 6

“The Effects of Nitrogen and Silicon Profile on High-K MOSFET Performance and Bias Temperature Instability” Changhwan Choi, et al., 2004 Symposium on VLSI Technology Digest of Technical Papers, pp. 214-215.

### SUMMARY

It is known that when a metal nitride film is used to form a gate electrode, as the thickness of the metal nitride film increases, long-term reliability of the pMOSFET, especially NBTI, is degraded. It is considered that degradation of the long-term reliability is caused by a phenomenon that nitrogen emitted from the metal nitride film nitrides the gate insulating film made of a high dielectric constant material and thereby increases the interface state of the substrate. To address this problem, the present inventors considered that nitrogen emitted from the metal nitride film needs to be prevented from reaching the gate insulating film. According to the method disclosed by Non-Patent Document 6 that controls the nitrogen distribution in the gate insulating layer by inserting an Si layer therein, the dielectric constant drops significantly at a portion of the gate insulating film into which the Si layer is inserted, and an SiO₂ equivalent effective oxide thickness (EOT) increases at an electrically efficient thickness of the gate insulating film. Non-Patent Document 6 reports data which shows a 10% or less variation in the EOT when the Si layer is inserted, as compared with the case where no Si layer is inserted, but no data is reported as to the thickness and the amount of deposit of HfO₂ which is a primary material of the gate insulating material. It is considered that when the Si layer is inserted, a thermal treatment removes oxygen from HfO₂ or HfON existing around the Si layer, and thereby the Si layer is oxidized and turns an Si oxide, which serves as part of the gate insulating film. In that case, it is considered that the formed Si oxide is nitrided by further introduction of nitrogen and turns Si oxynitride. Since the dielectric constant of the Si oxynitride is lower than that of HfO₂ and HfON, a gate insulating film formed by stacking Si oxynitride has a significantly low dielectric constant. Since oxygen is removed from the oxide existing around the Si layer, the oxide, from which oxygen is removed, exhibits metallic characteristics locally, but the dielectric strength thereof is degraded due to formation of the oxygen defect.

According to one aspect of the present invention, there is provided a semiconductor device which includes a substrate, a first gate insulating film which is formed on the substrate and made of a material having a dielectric constant higher than that of silicon oxynitride, a second gate insulating film which is formed on the first gate insulating film, contains silicon and is made of a material having a dielectric constant higher than that of silicon oxynitride, and a first gate electrode which is formed on the second gate insulating film and includes a metal nitride layer. The first gate insulating film, the second gate insulating film and the first gate electrode form part of a pMOSFET, the silicon-containing gate insulating film has a dielectric constant higher than that of the silicon oxynitride (SiON), and Si content of the silicon-containing second gate insulating film is less than 50% as compared with other metals or non-metals which form an insulating film and bond to oxygen.

According to another aspect of the present invention, the silicon-containing second gate insulating film is formed between the first gate insulating film and the first gate electrode. Thus, even when nitrogen contained in the first gate electrode moves toward the first gate insulating film, nitrogen is captured by silicon of the silicon-containing film. Therefore, nitrogen emitted from the metal nitride film is prevented from reaching the first gate insulating film. Further, since the silicon-containing second gate insulating film is a pre-oxidized insulating film, removal of oxygen from the first gate insulating film is suppressed. Moreover, the dielectric constant of the second gate insulating film can be designed in advance by adjusting the composition ration during the film formation more easily than a method disclosed by Non-Patent Document 6.

According to still another aspect of the present invention, there is provided a semiconductor device manufacturing method including the steps of: forming a first gate insulating film on a first element region in which a pMOSFET of a substrate is formed; the first gate insulating film made of a material having a dielectric constant higher than a dielectric constant of the oxynitride silicon, forming a second gate insulating film on the first gate insulating film, the second gate insulating film containing silicon and made of a material having a dielectric constant higher than a dielectric constant of the silicon oxynitride, and forming a first gate electrode on the second gate insulating film; the first gate electrode including a metal nitride layer.

According to the aspects of the present invention, nitrogen emitted from a metal nitride film can be prevented from reaching a first gate insulating film.

### BRIEF DESCRIPTION OF THE DRAWINGS

FIG. 1 is a cross sectional view showing a configuration of a semiconductor device according to a first embodiment;

FIGS. 2A and 2A are cross sectional views showing a method for manufacturing the semiconductor device shown in FIG. 1, in which FIG. 2A is a cross sectional view showing a method for forming films on a semiconductor substrate, and FIG. 2B is a cross sectional view showing a method for etching the films;

FIG. 3 is a cross sectional view showing a configuration of a semiconductor device according to a second embodiment;

FIG. 4 is a cross sectional view showing a configuration of a semiconductor device according to a third embodiment;

FIGS. 5A and FIG. 5A are cross sectional views showing a method for manufacturing the semiconductor device shown in FIG. 4, in which FIG. 5A is a cross section view showing a method for forming and etching films in a semiconductor substrate, and FIG. 5B is a cross section view showing a method for forming films and etching films on the semiconductor substrate; and

FIG. 6 is a cross sectional view showing a configuration of a semiconductor device according to a fourth embodiment.

### DETAILED DESCRIPTION

Hereinafter, preferred embodiments of the present invention are described with reference to the accompanying drawings. In all of the drawings, description of a similar component element is omitted by assigning a same reference numeral.

### First Embodiment

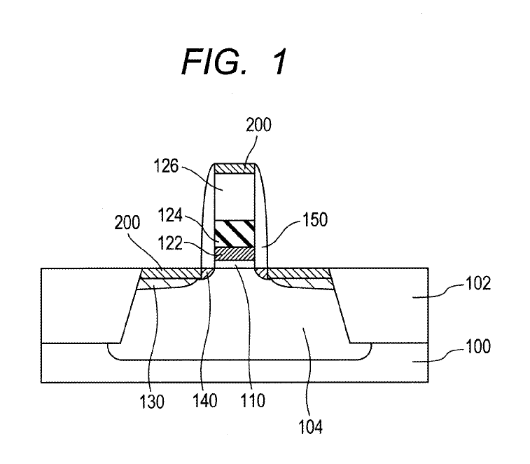

FIG. 1 is a cross sectional view showing a configuration of a semiconductor device according to a first embodiment. The semiconductor device includes a semiconductor substrate 100, a first gate insulating film 110, a silicon-containing second gate insulating film 122, and a first gate electrode. The first gate insulating film 110 is formed on the semiconductor substrate 100 and made of a material having a dielectric constant higher than that of silicon oxide or silicon oxynitride. The silicon-containing second gate insulating film 122 is formed on the first gate insulating film 110. The first gate electrode is formed on the silicon-containing second gate insulating film 122 and includes a metal nitride layer 124. The first gate insulating film 110, the silicon-containing second gate insulating film 122 and the metal nitride layer 124 form part of the pMOSFET. Hereinafter, details are described.

The semiconductor substrate 100 is, for example, a silicon substrate. However, the semiconductor substrate 100 may be an SOI substrate. In the semiconductor substrate 100, an element isolation film 102 is embedded. The element isolation film 102 isolates a first element region in which the pMOSFET is formed, from other regions.

In the first element region, an n-type well 104 is formed. In the n-type well 104, a source/drain region 130 which is a p-type diffusion layer, and an extension region 140 are formed. In a surface layer of the source/drain region 130, a silicide layer 200 is formed. The silicide layer 200 is, for example, an NiSi layer or a CoSi layer.

On the semiconductor substrate 100 located in the first element region, the first gate insulating film 110 and the first gate electrode are formed. As described above, the first gate insulating film 110 is formed by a material having a dielectric constant higher than that of silicon oxide or silicon oxynitride, for example, an HfLa oxide film, an HfLa rare-earth oxide film made by adding rare-earth other than La to the HfLa oxide film, or an HfY oxide film.

The first gate electrode includes the metal nitride layer 124 and a silicon layer 126. The metal nitride layer 124 is, for example, a TiN film or a TaN film, and the silicon layer 126 is, for example, a polysilicon layer. In a surface layer of the silicon 126, the silicide layer 200 is formed.

And, between the first gate insulating film 110 and the first gate electrode, the silicon-containing second gate insulating film 122 is formed. More particularly, the silicon-containing second gate insulating film 122 is located between the first gate insulating film 110 and the metal nitride layer 124. According to this embodiment, the silicon-containing second gate insulating film 122 is a metal silicate film, for example, an Hf silicate film. Thickness of the silicon-containing second insulating film 122 is, for example, 0.1 nm or more and 2 nm or less.

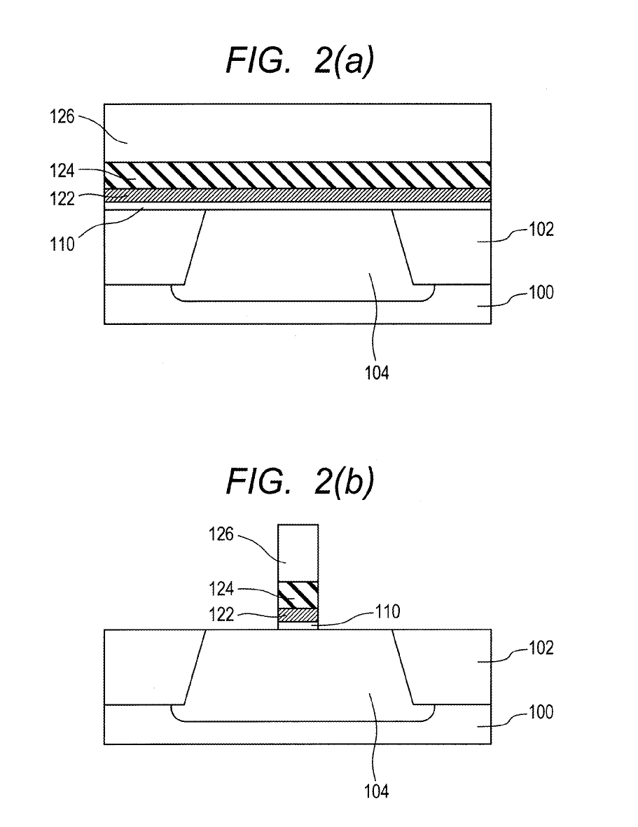

FIG. 2 is a cross sectional view showing a method for manufacturing the semiconductor device shown in FIG. 1. The method for manufacturing the semiconductor device includes the steps of: forming the first gate insulating film 110 on the semiconductor substrate 100, then forming the silicon-containing second gate insulating film 122 on the first gate insulating film 110, and then forming the first gate electrode on the silicon-containing second gate insulating film 122. Hereinafter, the manufacturing steps are described in detail.

Firstly, as shown in FIG. 2A, the element isolation film 102 and the n-type well 104 are formed in the semiconductor substrate 100. Next, the first gate insulating film 110 is formed on the semiconductor substrate 100 and the element isolation film 102. If the first gate insulating film 110 is an HfLa oxide film, the first gate insulating film 110 is formed by performing the steps of forming an HfO2 film, then forming a La film or a La oxide film, and then heating those stacked films. Next, on the first gate insulating film 110, the silicon-containing second gate insulating film 122, the metal nitride layer 124 and the silicon layer 126 are formed in this order.

The step of forming the metal nitride layer 124 and the silicon layer 126 is preferably performed in a continuous fashion without exposing to an oxidizing atmosphere or the atmosphere. For example, it is preferable that the metal nitride layer 124 and the silicon layer 126 are formed by using a system to which film forming devices independent from one another are connected via a vacuum transport path. In such a manner, an oxide layer is formed at an interface between the metal nitride layer 124 and the silicon layer 126, so that increase in a longitudinal resistance of the first gate electrode can be suppressed.

Next, as shown in FIG. 2B, a mask pattern, for example, a resist pattern (not shown) is formed on the silicon layer 126. Then, using the mask pattern as a mask, the silicon layer 126, the metal nitride layer 124, the silicon-containing second gate insulating film 122 and the first gate insulating film 110 are etched. Thus, the silicon layer 126, the metal nitride layer 124, the silicon-containing second gate insulating film 122 and the first gate insulating film 110 are selectively removed.

Then, using the silicon layer 126 and the element isolation film 102 as a mask, impurities for achieving a p-type conductivity in the semiconductor substrate 100 are implanted into the semiconductor substrate 100. Thus, the extension region 140 is formed. Then, after forming a side wall 150, impurities for achieving a p-type conductivity in the semiconductor substrate 100 are implanted into the semiconductor substrate 100 by using the silicon layer 126, the element isolation film 102 and the side wall 150 as a mask. Next, a thermal treatment for activating impurities in the extension region 140 and the source/drain region 130 is performed. Thus, the source/drain region 130 is formed. Next, a metal film is formed on the silicon layer 126 and the source drain region 130, and then a thermal treatment thereof is performed. Thus, the silicide layer 200 is formed.

Next, effects and advantages of this embodiment are described. In this embodiment, the metal nitride 124 is used in a portion of the first gate electrode. Therefore, when the thermal treatment for activating impurities in the extension region 140 and the source/drain region 130 is performed, nitrogen contained in the metal nitride layer 124 diffuses toward the first gate insulating film 100. In this embodiment, however, the silicon-containing second gate insulating film 122 is provided between the metal nitride layer 124 and the first gate insulating film 110, so that nitrogen diffusing from the metal nitride layer 124 toward the first gate insulating film 110 is captured by the silicon-containing second gate insulating film 122. Thus, nitrogen is prevented from reaching the first gate insulating film 110, so that increase in the interface state density of the semiconductor substrate 100 and increase in the thickness of the first gate insulating film 110 due to nitrogen can be suppressed. Consequently, degradation of the hole mobility in the pMOSFET can be suppressed, and thereby drop of the current driving capacity can be also suppressed. Moreover, since the increase in the interface state density is suppressed, degradation of the long-term reliability of the pMOSFET, for example, NBTI (Negative Bias Temperature Instability) can be suppressed as well. Furthermore, characteristics' variation of the pMOSFET resulting from increase of the EOT can be suppressed.

### Second Embodiment

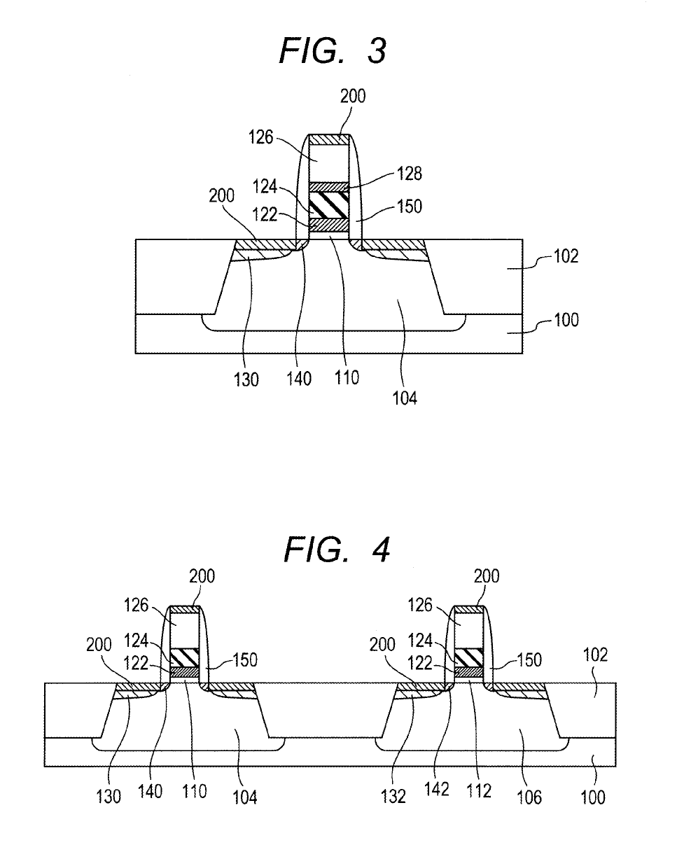

FIG. 3 is a cross sectional view showing a configuration of a semiconductor device according to a second embodiment. The semiconductor device according to this embodiment has a same configuration as that of the semiconductor device according to the first embodiment except that the semiconductor device includes a silicon-containing conductive film 128.

The silicon-containing conductive film 128 is located between the metal nitride layer 124 and the silicon layer 126 and includes silicon and an element other than silicon. The silicon-containing conductive film 128 is, for example, a metal silicide layer, more particularly, Ta silicide or W silicide. Thickness of the silicon-containing conductive film 128 is preferably thinner than the metal nitride layer 124, for example, 1 nm or more and 10 nm or less. With the thickness of the silicon-containing conductive film 128 thinner than that of the metal nitride layer 124, dimensional precision can be maintained under a shallow exposure focal depth by suppressing increase of the surface unevenness when adding layers in a subsequent exposure process in which the silicon-containing conductive film 128 is processed with the silicon layer 126.

A method for manufacturing the semiconductor device according to this embodiment is same as the method according to the first embodiment except that the method includes a step of forming the silicon-containing conductive film 128 on the metal nitride layer 124 after the step of forming the metal nitride layer 124 and before the step of forming the silicon layer 126.

This embodiment also provides same effects and advantages as those of the first embodiment. In addition, since the silicon-containing conductive film 128 is formed on the metal nitride 124, nitrogen emitted from the metal nitride layer 124 can be absorbed by the silicon-containing conductive film 128 as well. Therefore, nitrogen can be prevented from reaching the first gate insulating film 110.

### Third Embodiment

FIG. 4 is a cross sectional view showing a configuration of a semiconductor device according to a third embodiment. The semiconductor device includes an nMOSFET in addition to the pMOSFET. That is, the semiconductor device includes a CMOS.

More particularly, the semiconductor device includes a second element region in addition to the first element region. The second element region is isolated from the first element region by the element isolation film 102.

A semiconductor substrate 100 located in the second element region includes a p-type well 106, a source/drain region 132 and an extension region 142. On the semiconductor substrate 100 located in the second element region, a second gate insulating film 122, a silicon-containing second gate insulating film 122, a metal nitride layer 124 and a silicon layer 126 are formed in this order. A second gate insulating film 112 is made of a material which has a dielectric constant higher than that of silicon oxide and silicon oxynitride and is different from a material of the first gate insulating film 110. The second gate insulating film 112 is formed by, for example, an HfAl oxide film. On the surface of the source/drain region 132 and the silicon layer 126, the silicide layer 200 is formed.

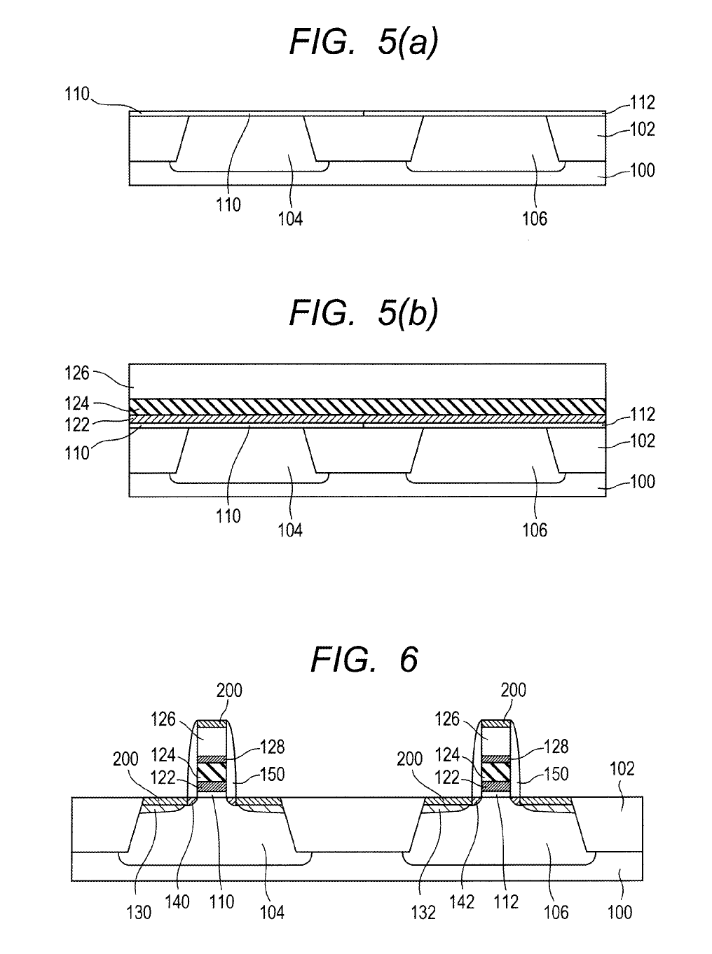

FIGS. 5A and 5B are cross sectional views showing a method for manufacturing the semiconductor device shown in FIG. 4. Firstly, as shown in FIG. 5A, the element isolation film 102, the n-type well 104 and the p-type well 106 are formed on the semiconductor substrate 100. Next, the first gate insulating film 110 is formed on the semiconductor substrate 100 and the element isolation film 201. Then, the first gate insulating film 110 located on and around the p-type well 106 is removed selectively. Then, the second gate insulating film 112 is formed on the semiconductor substrate 100 and the element isolation film 102. Then, the second gate insulating film 112 located on and around the n-type well 104 is removed selectively.

Next, as shown in FIG. 5B, on the first gate insulating film 110 and the second gate insulating film 112, the silicon-containing second gate insulating film 122, the metal nitride layer 124 and the silicon layer 126 are formed in this order. This method of forming is same as that of the first embodiment.

Next, a mask pattern, for example, a resist pattern, is formed on the silicon layer 126. Using the mask pattern as a mask, the silicon layer 126, the metal nitride layer 124, the silicon-containing second gate insulating film 122, the first gate insulating film 110 and the second gate insulating film 112 are etched. Thus, a gate structure of the pMOSFET and a gate structure of the nMOSFET are formed.

Then, the second element region is covered with a resist film. Then, using the resist film, the silicon layer 126 and the element isolation film 102 as a mask, impurities for achieving a p-type conductivity in the semiconductor substrate 100 are implanted into the semiconductor substrate 100. Thus, the extension region 140 is formed. Thereafter, the resist film is removed. Then, the first element region is covered with a resist film. Then, using the resist film, the silicon layer 126 and the element isolation film 102 as a mask, impurities for achieving an n-type conductivity in the semiconductor substrate 100 are implanted into the semiconductor substrate 100. Thus, the extension region 142 is formed.

Next, the side wall 150 is formed. Then, the second element region is covered with a resist film. Then, using the resist film, the silicon layer 126, the element isolation film 102 and the side wall 150 as a mask, impurities for achieving a p-type conductivity in the semiconductor substrate 100 are implanted into the semiconductor substrate 100. Thus, a source/drain region 130 is formed. Thereafter, the resist film is removed. Next, the first element region is covered with a resist film. Then, using the resist film, the silicon layer 126, the element isolation film 102 and the side wall 150 as a mask, impurities for achieving an n-type conductivity in the semiconductor substrate 100 are implanted into the semiconductor substrate 100. Thus, a source/drain region 132 is formed.

Then, a thermal treatment for activating impurities in extension regions 140, 142 and source/drain regions 130, 132 is performed. Then, a metal film is formed on the silicon layer 126 and the source/drain region 130 and a thermal treatment thereof is performed. Thus, a silicide layer 200 is formed.

According to this embodiment, same effects as the first embodiment can be obtained for the pMOSFET. For the nMOSFET, since increase in the interface state formed at an interface between a gate insulating film and an Si substrate obtained according to the first embodiment is suppressed, reduction of the electron mobility due to the interface state is suppressed, and degradation of the current driving capacity is suppressed. Fourth Embodiment

FIG. 6 is a cross sectional view showing a configuration of a semiconductor device according to a fourth embodiment. The semiconductor device according to this embodiment is same as the semiconductor device according to the third embodiment except that both of the nMOSFET and the pMOSFET include the silicon-containing conductive film 128. Position and configuration of the silicon-containing conductive film 128 are same as those of the second embodiment.

According to this embodiment, the same effects as those of the second embodiment can be obtained. In addition, effects of the nMOSFET according to the third embodiment can be also obtained.

The present invention has been described in connection with the preferred embodiments with reference to the accompanying documents, but the present invention is not limited to the above embodiments only. It will be apparent to those skilled in the art that various configurations other than the above can be adopted as well.

What is claimed is:

1. A semiconductor device, comprising:
a substrate;
a first gate insulating film which is formed on the substrate and made of a material having a dielectric constant higher than a dielectric constant of silicon oxynitride;
a second gate insulating film which is formed on the first gate insulating film, contains silicon and is made of a material having a dielectric constant higher than a dielectric constant of silicon nitride; and
a first gate electrode which is formed on the second gate insulating film and contains a metal nitride layer,
wherein the first gate insulating film, the second gate insulating film and the first gate electrode are part of a pMOSFET.

2. The semiconductor device according to claim 1,
wherein the second gate insulating film is a metal silicate film.

3. The semiconductor device according to claim 2,
wherein the first gate insulating film is an HfLa oxide film, an HfLa rare-earth oxide film made by adding a rare-earth other than La to the HfLa oxide film, or an HfY oxide film, and
wherein the second gate insulating film is an Hf silicate film.

4. The semiconductor device according to claim 1,
wherein the first gate electrode is formed on the metal nitride layer and includes a silicon-containing conductive film containing silicon and an element other than silicon, and a silicon layer formed on the silicon-containing conductive film.

5. The semiconductor device according to claim 4,
wherein the silicon-containing conductive film is a metal silicide film.

6. The semiconductor device according to claim 5,
wherein the silicon-containing conductive film is Ta silicide or W silicide.

7. A semiconductor device manufacturing method, the method comprising:
forming a first gate insulating film on a first element region in which a pMOSFET of a substrate is formed, the first gate insulating film made of a material having a dielectric constant higher than a dielectric constant of silicon oxynitride;
forming a second gate insulating film on the first gate insulating film; the second gate insulating film containing silicon and made of a material having a dielectric constant higher than a dielectric constant of silicon oxynitride; and
forming a first gate electrode on the second gate insulating film, the first gate electrode containing a metal nitride layer.

8. The semiconductor device manufacturing method according to claim 7,
wherein the substrate includes a second element region in which an nMOSFET is formed, and the first element region,
wherein, in said forming the first gate insulating film, the first gate insulating film is formed on the second element region and the first gate insulating film is not formed on the first element region,
wherein, after said forming the first gate insulating film and before said forming the second gate insulating film, a third gate insulating film made of a material having a dielectric constant higher than a dielectric constant of silicon oxide is formed on the first element region,
wherein, in said forming the second gate insulating film, the second gate insulating film is formed on the first gate insulating film and the third gate insulating film, and
wherein, in said forming the first gate insulating film, a second gate electrode is formed on the second gate insulating film located in the second element region in a same step as the step of forming the first gate electrode.
